(19) United States
(12) Patent Application Publication
(10) Pub. No.: US 2013/0213472 A1
(43) Pub. Date: Aug. 22, 2013

(54) LUMINESCENT SOLAR CONCENTRATOR APPARATUS, METHOD AND APPLICATIONS

(71) Applicants: David Powell, Boulder, CO (US); Glenn Alers, Scotts Valley, CA (US); Jeremy Olson, Placerville, CA (US)

(72) Inventors: David Powell, Boulder, CO (US); Glenn Alers, Scotts Valley, CA (US); Jeremy Olson, Placerville, CA (US)

(73) Assignee: ABENGOA SOLAR PV LLC, Lakewood, CO (US)

(21) Appl. No.: 13/883,340

(22) PCT Filed: Nov. 2, 2011
(86) PCT No.: PCT/US2011/058900

§ 371 Date: May 3, 2013

Related U.S. Application Data
(60) Provisional application No. 61/409,589, filed on Nov. 3, 2010.

(51) Int. Cl. H01L 31/055; H01L 31/18

(52) U.S. Cl. CPC H01L 31/055; H01L 31/18
USPC 136/257; 438/69

(57) ABSTRACT

A luminescent solar concentrator apparatus includes an optically transparent substrate and a photovoltaic material layer at least partially embedded within an optically transparent encapsulant material layer that contacts the optically transparent substrate. A luminescent material layer also contacts the optically transparent encapsulant material layer. Generally, the luminescent solar concentrator apparatus provides that the luminescent material layer is not located within an incoming optical pathway through at least the optically transparent substrate to the photovoltaic material layer.

### CROSS-REFERENCE TO RELATED APPLICATION

This application is related to, and derives priority from, U.S. Provisional Patent application serial number 61/409,589, filed 3 Nov. 2010, and titled Luminescent Solar Concentrator Apparatus, Method and Applications, the content of which is incorporated herein fully by reference.

### BACKGROUND

1. Field of the Invention

Embodiments relate generally to photovoltaic energy conversion. More particularly, embodiments relate to luminescent solar concentrator apparatuses and methods within the context of photovoltaic energy conversion.

2. Description of the Related Art

Luminescent solar concentrator apparatuses have been employed for several decades as a means to reduce costs of photovoltaic energy conversion systems. To that end, luminescent solar concentrator apparatuses provide an efficient means to collect incident solar radiation over large surface areas and to guide the incident solar radiation onto much smaller surface area photovoltaic cells for conversion into electricity.

A typical luminescent solar concentrator apparatus panel is generally in the form of a flat, high-aspect ratio (x, y >>thickness, z) plate or window. The luminescent solar concentrator apparatus panel may consist of, or alternatively comprise, a luminescent material, usually in an at least partially transparent binder or carrier. The luminescent material absorbs incident solar radiation and then re-radiates luminescent radiation at a different wavelength for capture and conversion by a photovoltaic cell.

Within a luminescent solar concentrator apparatus, a majority of the re-radiated luminescent radiation is totally internally reflected from the large (x, y) internal surfaces, as known in the art, until the re-radiated luminescent radiation impinges upon the photovoltaic cell. Nonetheless, light that is lost through the x, y surfaces or reabsorbed by the luminescent material, or otherwise not incident upon the photovoltaic cell, is not converted into electricity. Such conversion losses may be significant and costly.

Thus, desirable are luminescent solar concentrator apparatuses and methods that provide for minimized incoming solar radiation losses and maximized incoming solar radiation conversion within the context of the luminescent solar concentrator apparatuses and methods.

### SUMMARY

Embodiments include a plurality of luminescent solar concentrator apparatuses and a related method for fabricating the plurality of luminescent solar concentrator apparatuses. Most generally, the luminescent solar concentrator apparatuses in accordance with the embodiments include a photovoltaic material layer and a luminescent material layer located over a transparent substrate, where the luminescent material layer is not within an incoming optical pathway through the transparent substrate to the photovoltaic material layer. More specific embodiments of the luminescent solar concentrator apparatuses in accordance with the embodiments comprise a photovoltaic material layer located at least partially embedded within an optically transparent encapsulant material layer that in turn contacts an optically transparent substrate to provide an incoming optical pathway to the photovoltaic material layer through at least the optically transparent substrate, and typically also the optically transparent encapsulant material layer. The luminescent solar concentrator apparatuses in accordance with the more specific embodiments also include a luminescent material layer located contacting the optically transparent encapsulant material layer, but not within the incoming optical pathway to the photovoltaic material layer through at least the optically transparent substrate, and typically also the optically transparent encapsulant material layer.

Thus, a luminescent solar concentrator apparatus in accordance with the embodiments provides for: (1) photovoltaic conversion of solar radiation directly incident upon a photovoltaic material layer (i.e., alternatively a strip photovoltaic cell or a grid photovoltaic cell) without passing through a luminescent material layer within a luminescent solar concentrator apparatus in accordance with the embodiments; (2) photovoltaic conversion of totally internally reflected incident solar radiation incident upon a photovoltaic material layer within a luminescent solar concentrator apparatus in accordance with the embodiments; and (3) photovoltaic conversion of totally internally reflected luminescent radiation incident upon a photovoltaic material layer within a luminescent solar concentrator apparatus in accordance with the embodiments.

A particular luminescent solar concentrator apparatus in accordance with the embodiments includes an optically transparent substrate. This particular luminescent solar concentrator apparatus also includes a photovoltaic material layer located over the optically transparent substrate. This particular luminescent solar concentrator apparatus also includes a luminescent material layer also located over the optically transparent substrate. Within the luminescent solar concentrator apparatus, the luminescent material layer is not within an incoming optical pathway through at least the optically transparent substrate to the photovoltaic material layer.

Another particular luminescent solar concentrator apparatus in accordance with the embodiments includes an optically transparent substrate. This particular luminescent solar concentrator apparatus also includes a photovoltaic material layer located at least partially encapsulated within an optically transparent encapsulant material layer located over the optically transparent substrate. This particular luminescent solar concentrator apparatus also includes a luminescent material layer located contacting the optically transparent encapsulant material layer and not within an incoming optical pathway through at least the optically transparent substrate to the photovoltaic material layer.

Yet another particular luminescent solar concentrator apparatus in accordance with the embodiments includes an optically transparent substrate. This other particular luminescent solar concentrator apparatus also includes a photovoltaic material layer located encapsulated within an optically transparent encapsulant material layer located over one side of the optically transparent substrate. This other particular luminescent solar concentrator apparatus also includes a luminescent material layer located over a side of the optically transparent encapsulant material layer opposite the optically transparent substrate.

Yet another particular luminescent solar concentrator apparatus in accordance with the embodiments includes an optically transparent substrate. This other particular luminescent solar concentrator apparatus also includes a photovoltaic material layer located at least partially encapsulated within an optically transparent encapsulant material layer located over one side of the optically transparent substrate. This other luminescent solar concentrator apparatus also includes a luminescent material layer located interposed between the optically transparent substrate and the optically transparent encapsulant material layer and not within an incoming optical pathway through at least the optically transparent substrate to the photovoltaic material layer.

A method for fabricating a luminescent solar concentrator apparatus in accordance with the embodiments includes forming over an optically transparent substrate an optically transparent encapsulant material layer including a photovoltaic material layer at least partially encapsulated within the optically transparent encapsulant material layer. This particular method also includes forming over the optically transparent substrate a luminescent material layer that is not located in an incoming optical pathway through at least the optically transparent substrate to the photovoltaic material layer.

Within the context of the following description and the accompanying claims, use of the terminology “over” is intended to indicate a relative location of one layer or structure either beneath or above another layer or structure with the possibility, but not the requirement, that the two particular layers or structures contact. By contrast, use of the terminology “upon” is intended to indicate the relative location of one layer or structure either beneath or above another layer or structure, and also include the requirement that the two particular layers or structures contact. In addition, within the context of the following description and the accompanying claims, use of the terminology “interposed” is intended to indicate a relative location of one layer or structure between at least two other layers or structures with the possibility, but not the requirement, that any two or more of the layers or structures contact.

Within the context of the foregoing definitions of “over” and “upon,” the following description contemplates, for example, that a luminescent solar concentrator apparatus may be fabricated in one disposition (i.e., starting with an optically transparent substrate as a base substrate upon or over which are located and formed additional layers and structures) and rotated 180 degrees in an opposite disposition in use to provide that the optically transparent substrate provides an exposed surface for incident solar radiation whose photovoltaic conversion is desired.

### BRIEF DESCRIPTION OF THE DRAWINGS

The objects, features and advantages of the embodiments are understood within the context of the Detailed Description of the Embodiments, as set forth below. The Detailed Description of the Embodiments is understood within the context of the accompanying drawings, that form a material part of this disclosure, wherein:

FIG. 1A shows a schematic cross-sectional view diagram of a luminescent solar concentrator apparatus in accordance with a first embodiment.

FIG. 1B shows a schematic plan-view diagram of the luminescent solar concentrator apparatus in accordance with the first embodiment.

FIG. 2 shows a schematic cross-sectional view diagram of a luminescent solar concentrator apparatus in accordance with a second embodiment.

FIG. 3A shows a schematic cross-sectional view diagram illustrating total internal reflection considerations within a luminescent solar concentrator apparatus not in accordance with the embodiments.

FIG. 3B shows a schematic cross-sectional view diagram illustrating total internal reflection considerations within a luminescent solar concentrator apparatus in accordance with the embodiments.

### DETAILED DESCRIPTION OF THE EMBODIMENTS

The embodiments, which include a plurality of luminescent solar concentrator apparatuses, and a related method for fabricating the plurality of luminescent solar concentrator apparatuses, are understood within the context of the detailed description, as set forth below. The detailed description as set forth below is understood within the context of drawings described above. Since the drawings are intended for illustrative purposes, the drawings are not necessarily drawn to scale.

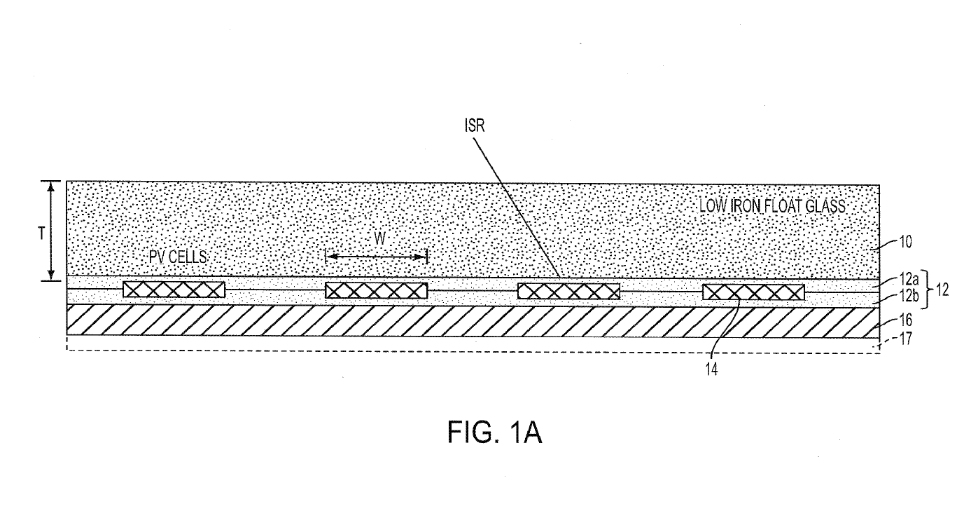

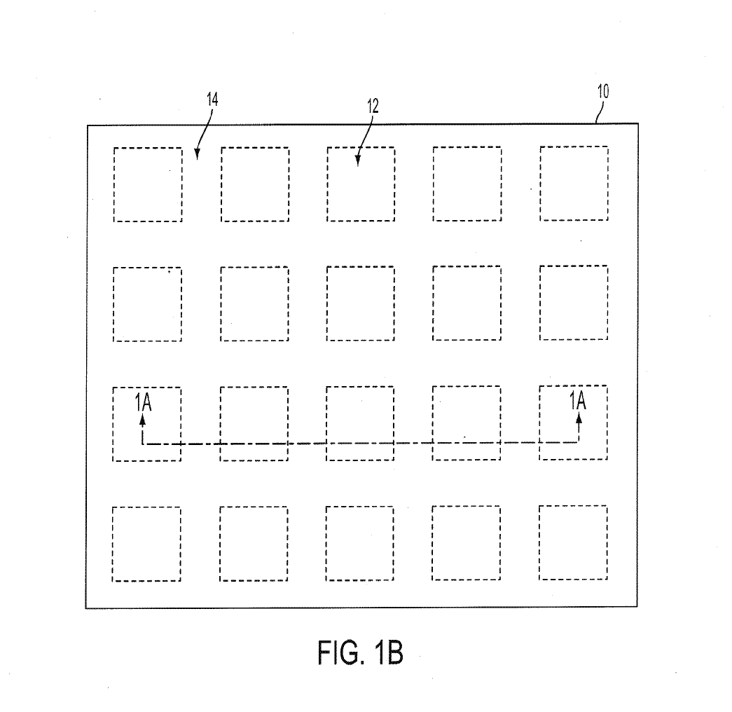

FIG. 1A shows a schematic cross-sectional view diagram of a luminescent solar concentrator apparatus in accordance with a first embodiment.

This particular luminescent solar concentrator apparatus in accordance with the first embodiment comprises in a first instance a transparent substrate 10. An encapsulant material layer 12 (which comprises a first encapsulant material sub-layer 12a and a second encapsulant material sub-layer 12b) is located and formed over and contacting one side of the transparent substrate 10. Incorporated within the encapsulant material layer 12 and interposed between and contacting the first encapsulant material sub-layer 12a and the second encapsulant material sub-layer 12b is a plurality of photovoltaic material layers 14 (i.e., each having a width W planar with the transparent substrate 10) that are intended as either individual photovoltaic material layers as photovoltaic cells, or a single interconnected photovoltaic material layer photovoltaic cell. FIG. 1 also shows located and formed over and contacting a side of the encapsulant material layer 12 opposite the transparent substrate 10 a luminescent material layer 16, and FIG. 1A also shows an optional barrier layer 17 located and formed over and contacting a side of the luminescent material layer 16 opposite the encapsulant material layer 12. Finally, FIG. 1A illustrates a dimension T which is intended as a thickness of a totally internally reflective material (i.e., totally internally reflective material layers) located over the photovoltaic material layers 14 (i.e., this will typically be approximated as a thickness of the transparent substrate 10, but more specifically within the context of the first embodiment includes a thickness of the transparent substrate 10 and a portion of the thickness of the first encapsulant material sub-layer 12a).

For reference purposes, FIG. 1A also illustrates an incoming solar radiation ISR beam which travels through the transparent substrate 10 and a portion of the first encapsulant material sub-layer 12a, but not the luminescent material layer 16, to reach the photovoltaic material layer 14. As is noted above, this operational geometric disposition of the luminescent solar concentrator apparatus in accordance with the embodiments is generally opposite to a geometric disposition during fabrication.

Particular compositions and materials of construction for each of the foregoing layers and structures of a luminescent solar concentrator apparatus in accordance with the first embodiment are described in further detail as follows.

First, the transparent substrate 10 comprises a transparent material that is transparent in particular to a spectrum of incident radiation (i.e., usually incident solar radiation) whose quantity it is desired to concentrate using the luminescent solar concentrator apparatus in accordance with the first embodiment whose schematic cross-sectional view diagram is illustrated in FIG. 1A. Commonly, the transparent substrate 10 may comprise an inorganic transparent substrate material, such as but not limited to a glass, and in particular a silicate glass. Alternatively, the transparent substrate 10 may comprise an organic transparent substrate material, such as but not limited to an organic polymer organic transparent substrate material, and in particular a polymethylmetharcyalate (PMMA) polymer sheet organic polymer organic transparent substrate material. Typically and preferably, the transparent substrate 10 comprises a glass transparent substrate material, such as but not limited to a silicate glass transparent substrate material, that has a thickness from about 1 to about 25 millimeters, and more preferably from about 2 to about 10 millimeters.

Next, the encapsulant material layer 12 (i.e., more particularly including the first encapsulant material sub-layer 12a and the second encapsulant material sub-layer 12b) comprises an encapsulant material consistent with ready fabrication of the luminescent solar concentrator apparatus in accordance with the first embodiment as illustrated in FIG. 1A. Such an encapsulant material is also preferably optically transparent to an incoming radiation spectrum whose quantity it is desired to concentrate while using the luminescent solar concentrator apparatus whose schematic cross-sectional view diagram is illustrated in FIG. 1A. Although other encapsulant materials are not excluded within the embodiments, the encapsulant material layer 12 typically and advantageously comprises an organic polymer encapsulant material that possesses the desirable optical transparency and clarity. Common organic polymer encapsulant materials include, but are not limited to, ethylenevinylacetate (EVA) organic polymer encapsulant materials, polyvinylbutyral (PVB) organic polymer encapsulant materials and polyolefin organic polymer encapsulant materials (i.e., such as but not limited to polyethylene organic polymer encapsulant materials and polypropylene organic polymer encapsulant materials), although other organic polymer encapsulant materials are not excluded. Typically, the encapsulant material layer 12 comprises an ethylenevinylacetate organic polymer encapsulant material that has a thickness from about 0.1 to about 5 millimeters and more preferably from about 0.1 to about 1 millimeters, where each of the first encapsulant material sub-layer 12a and the second encapsulant material sub-layer 12b has a thickness from about 0.1 to about 5 millimeters and more preferably from about 0.1 to about 1 millimeters.

Within this first embodiment, the encapsulant material layer 12b in particular may comprise a moisture and corrosion barrier encapsulant material with respect to the photovoltaic material layers 14. Alternatively, the luminescent material layer 16 or the additional barrier layer 17 located and formed over and contacting the luminescent material layer 16 may also comprise the moisture and corrosion barrier material with respect to the photovoltaic material layers 14.

Next, the photovoltaic material layers 14 may comprise any of several photovoltaic materials. Common photovoltaic materials from which may be comprised the photovoltaic material layers 14 include silicon photovoltaic materials, as well as any of several other types of photovoltaic materials (i.e., copper, indium, gallium, selenium, and gallium arsenide photovoltaic materials; as well as organic photovoltaic materials). Typically, the photovoltaic material layers 14 comprise a silicon photovoltaic material that has a thickness from about 0.02 to about 5 millimeters, more preferably from about 0.02 to about 2 millimeters and most preferably from about 0.02 to about 1 millimeter.

As is understood by a person skilled in the art, the photovoltaic material layers 14 may be arranged and fully embedded within the encapsulant material layer 12 and interposed between the transparent substrate 10 and the luminescent material layer 16 in any of several geometric arrangements. Such geometric arrangements may include, but are not necessarily limited to, a window pane arrangement as is discussed below within the context of the description of FIG. 1B.

The luminescent material layer 16 comprises at least one luminescent material. Such a luminescent material may be selected from the group of any of several luminescent materials that are generally conventional, as well as luminescent materials that are otherwise not generally conventional. Typically, the luminescent material layer 16 comprises an organic luminescent dye luminescent material, or an alternative luminescent material that is dispersed or dissolved in a suitable binder material, which may include, but is not necessarily limited to a polymethylmethacrylate (PMMA) binder material. Typically, the luminescent material layer 16 has a thickness from about 0.1 to about 3 millimeters, and more preferably 0.1 to about 2 millimeters when comprising the organic luminescent dye material dispersed or dissolved in the suitable binder material. However, in accordance with further description below alternative luminescent materials, such as but not limited to semiconducting polymer luminescent materials, are also feasible within the embodiments. Such semiconducting polymer luminescent materials may be applied at a thickness in a range from about 10 to about 200 microns, thus providing an extended thickness range for the luminescent material layer 16 from about 10 microns to about 3 millimeters.

According to various non-limiting aspects consistent with the above, the incoming solar radiation absorbing luminescent material within the luminescent material layer 16 may alternatively be in the form of quantum dots or a luminescent polymer material, and in particular a luminescent semiconducting polymer material. Under such circumstances, a luminescent semiconducting polymer material film should be thick enough to absorb most of the incoming solar radiation incident upon the luminescent solar concentrator apparatus in accordance with the first embodiment as illustrated in FIG. 1A within the semiconducting polymer absorption spectrum after one or two passes through the semiconducting polymer material film.

Advantageously, the luminescent material layer 16 desirably absorbs any range of wavelengths available in the solar spectrum, and a luminescent material within the luminescent material layer 16 should have a fluorescence quantum yield of more than 50%, with little overlap between the absorption spectrum and the fluorescence spectrum (i.e., no greater than about 10 percent area overlap with respect to either the absorption peak area or the fluorescence peak area). Desirably, the photovoltaic material layers 14 as photovoltaic cells may be matched to optimally photovoltaically respond to the fluorescence wavelength range of the luminescent material within the luminescent material layer 16.

With respect to luminescent semiconducting polymers, and unlike luminescent dyes that may be used within luminescent solar concentrator apparatus and are generally protected from oxygen and water, and which must be dilute because of self-quenching, many luminescent semiconducting polymers do not self-quench. Thus, high optical absorption can be achieved from a thin film of a luminescent semiconducting polymer material as a luminescent material layer 16. Luminescent semiconducting polymers also typically have a broader absorption spectrum in comparison with a luminescent dye absorption spectrum, thus increasing the fraction of solar radiation absorbed, and also luminescent semiconducting polymers typically have a larger Stoke's shift, thus reducing self absorption.

In various non-limiting aspects, a luminescent semiconducting polymer for use as a luminescent material within a luminescent material layer 16 may be selected from a class of conjugated polymers with high photoluminescence quantum yield that are derived from benzothiazole, carbazole fluorine, phenylene, phenylenevinylene, thiophene and related materials. These polymers include polyfluorenes, polyvinylene phenylenes, polypentaphenylenes, polyfluroenylene ethynylenes, polyphenylethynylene, polyfluorene-vinylene, and polythiophenes. Other luminescent materials that may be used within the luminescent material layer 16 may include Lumogen F Red305 (BASF), Exciton, laser dyes, IR dyes, anisotropic fluorescent dyes, and others known in the art.

Also, as is understood by a person skilled in the art, and as is discussed further below, the luminescent materials from which is comprised or from which consists the luminescent material layer 16 may be mixed at very specific concentrations to optimize absorption and emission characteristics, or alternatively to tune a wavelength, for matching with a particular photovoltaic cell composition or for a specific color in building integrated photovoltaic (BIPV) applications (i.e., such as but not limited to windows, tiles and blinds upon which solar radiation may be incident). Further with respect to such color matching, the embodiments also contemplate the use of an additional non-luminescent dye within the luminescent material layer or some other layer within the luminescent solar concentrator apparatus in accordance with the first embodiment as illustrated in FIG. 1A, or alternatively some additional color filter that may be provided as an additional separate layer or separate component.

Finally, the optional barrier layer 17 may comprise any of several barrier materials intended to provide moisture and corrosion protection to the photovoltaic material layers 14, as well as the luminescent materials within the luminescent material layer 16. To that end, the barrier layer 17 may comprise barrier materials including but not limited to polymethylmethacrylate barrier materials. Typically and preferably, the barrier layer 17 comprises a polymethylmethacrylate barrier material that has a thickness from about 0.1 to about 5 millimeters.

FIG. 1A shows a schematic cross-sectional view diagram of a luminescent solar concentrator apparatus in accordance with a particular first embodiment. Such a luminescent solar concentrator apparatus in accordance with the first embodiment allows for efficient capture of incoming solar radiation directly insofar as there is no light absorbing material (i.e., no luminescent material layer 16) located and formed interposed between a solar radiation source (i.e., located above an exposed surface of the optically transparent substrate 10) and a photovoltaic material layer 14 within the luminescent solar concentrator apparatus. Moreover, due to the presence of the encapsulant material sub-layer 12b and the luminescent material layer 16 on a backside of the luminescent solar concentrator apparatus, the luminescent solar concentrator apparatus in accordance with this particular embodiment may also provide for additional environmental protection as a barrier layer with respect to the photovoltaic material layers 14.

As is understood by a person skilled in the art, the luminescent solar concentrator apparatus in accordance with the first embodiment an as illustrated in FIG. 1A also collects at the photovoltaic material layers 14 additional radiation through total internal reflection (i.e., interposed between the outer surfaces of the transparent substrate 10 and the luminescent material layer 16 or optional barrier layer 17) with respect to both: (1) incoming solar radiation from above the exposed surface of the transparent substrate 10; and (2) luminescent radiation that is emitted from a luminescent material that is included within the luminescent material layer 16.

FIG. 1B shows a schematic plan-view diagram of a luminescent solar concentrator apparatus corresponding with the luminescent solar concentrator apparatus whose schematic cross-sectional diagram is illustrated in FIG. 1A. FIG. 1B shows the optically transparent substrate 10 as a surface layer, with a single grid that comprises a single photovoltaic material layer 14. Exposed within the single grid that comprises the single photovoltaic material layer 14 is a plurality of exposed portions of the encapsulant material layer 12 that resemble individual window panes.

The luminescent solar concentrator apparatus whose schematic cross-sectional diagram is illustrated in FIG. 1A and whose schematic plan-view diagram is illustrated in FIG. 1B may be fabricated using any of several methods, including but not limited to coating methods, lamination methods and other assembly methods. Most typically, one may in particular start with a transparent substrate 10 as a base substrate upon and over which may be fabricated additional layers and structures within the first embodiment of the luminescent solar concentrator apparatus whose schematic cross-sectional view diagram is illustrated in FIG. 1A and whose schematic plan view diagram is illustrated in FIG. 1B. A first portion of the encapsulant material layer 12 (i.e., the first encapsulant material sub-layer 12a) may then be located and formed upon (i.e., contacting) the optically transparent substrate 10. Individual photovoltaic material layers 14 or an interconnected grid comprising a single photovoltaic material layer 14 (i.e., as illustrated within the schematic plan view diagram of FIG. 1B) may then be located, assembled and aligned upon the first portion of the encapsulant material layer 12, along with connections to provide photovoltaic cells from the photovoltaic material layers 14. A second portion of the encapsulant material layer 12 (i.e., the second encapsulant material sub-layer 12b) may then be laminated to the exposed portions of the first portion of the encapsulant material layer 12 and the photovoltaic material layers 14. Finally, the luminescent material layer 16 may then be laminated or coated upon the exposed portion of the second portion of the encapsulant material layer 12 and the barrier layer 17 may then be laminated or coated upon the exposed portion of the luminescent material layer 16.

As is understood by a person skilled in the art, the luminescent solar concentrator apparatus whose schematic cross-sectional diagram is illustrated in FIG. 1A and whose schematic plan view diagram is illustrated in FIG. 1B provides particular value insofar as at least some portion of incoming solar radiation travels through only an optically transparent substrate 10 and a portion of an optically transparent encapsulant material layer 12 prior to being captured by a photovoltaic material layer 14. In addition, within the luminescent solar concentrator apparatus in accordance with the first embodiment as illustrated in FIG. 1A the second encapsulant material sub-layer 12b and the luminescent material layer 16 may provide protection for the photovoltaic material layers 14 from moisture and corrosion.

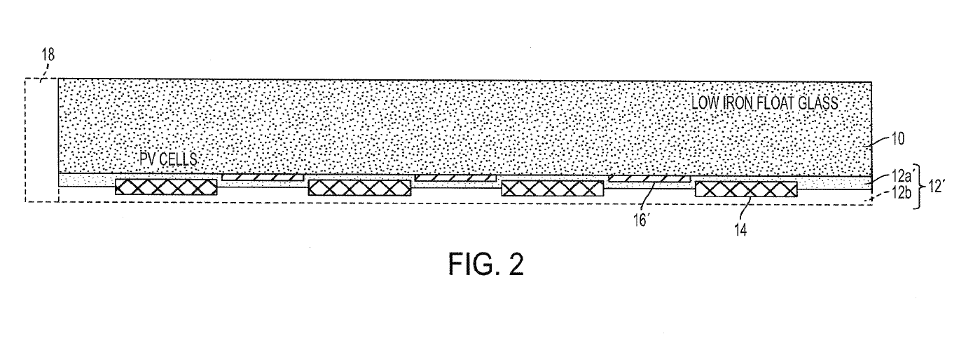

FIG. 2 shows a schematic cross-sectional view diagram of a luminescent solar concentrator apparatus in accordance with a second embodiment.

Within the luminescent solar concentrator apparatus in accordance with the second embodiment as illustrated within the schematic cross-sectional diagram of FIG. 2, the layers and structures are generally similar with the layers and structures that are illustrated in the luminescent solar concentrator apparatus in accordance with the first embodiment as illustrated in FIG. 1A, but with the following exceptions. First, a top surface and interface of an encapsulant material layer 12′ (that in particular comprises a first encapsulant material sub-layer 12a′ and a second encapsulant material sub-layer 12b) with the bottom surface of the transparent substrate 10 is not entirely planar as illustrated within the schematic cross-sectional diagram of FIG. 1A with respect to the encapsulant material layer 12. In addition the second portion of the encapsulant material layer 12 (i.e., the encapsulant material sub-layer 12b) is optional within the second embodiment, but when present provides protection of the photovoltaic material layers 14 against environmental exposure and corrosion. Further, the sizing and location of luminescent material layer 16 that is illustrated in FIG. 1 is changed to instead provide a plurality of luminescent material layers 16′ located and formed vertically interposed between the transparent substrate 10 and the encapsulant material layer 12′ (i.e., more particularly the encapsulant material sub-layer 12a′), and also horizontally interposed between the photovoltaic material layers 14. Finally, the luminescent solar concentrator apparatus in accordance with the second embodiment as illustrated within the schematic cross-sectional diagram of FIG. 2 also shows an edge reflector 18 which may be used on any of the edges of either of the luminescent solar concentrator apparatus of the first embodiment or the second embodiment to provide for reduced light loss and enhanced light conversion.

FIG. 2 thus shows a schematic cross-sectional diagram of a luminescent solar concentrator apparatus in accordance with a second embodiment. Similarly with the luminescent solar concentrator apparatus in accordance with the first embodiment as illustrated in FIG. 1A and FIG. 1B, the luminescent solar concentrator apparatus in accordance with the second embodiment as illustrated in the schematic cross-sectional view diagram of FIG. 2 provides for direct capture of solar photonic radiation that is directly incident upon a plurality of photovoltaic material layers 14 after traveling through only the transparent substrate 10 and selected portions of the first encapsulant material sub-layer 12a′ but not the luminescent material layers 16′. In addition, the luminescent solar concentrator apparatus whose schematic cross-sectional diagram is illustrated in FIG. 2 also captures totally internally reflected solar radiation and totally internally reflected luminescent radiation that is totally internally reflected between an outer surface of the optically transparent substrate 10 and either the first encapsulant material sub-layer 12a′ or the optional second encapsulant material sub-layer 12b.

The luminescent solar concentrator apparatus whose schematic cross-sectional diagram is illustrated in FIG. 2 may in general be fabricated using methods that are generally similar with the methods used for fabricating the luminescent solar concentrator apparatus whose schematic cross-sectional view diagram is illustrated in FIG. 1A and whose schematic plan-view diagram is illustrated in FIG. 1B insofar as one may start with a transparent substrate 10. Within this second embodiment, however, rather than using a luminescent material layer 16 that comprises or is intended at least in part as a barrier material layer, the luminescent material layers 16′ may be screen printed, gravure printed or painted onto the transparent substrate 10 in a desired pattern directly upon the transparent substrate 10. Similarly, after laminating an encapsulant material sub-layer 12a′ upon the resulting composite of the transparent substrate 10 and the luminescent material layers 16′, the photovoltaic material layers 14 that are otherwise unchanged from the first embodiment as illustrated in FIG. 1A and FIG. 1B may be assembled to the encapsulant material sub-layer 12a′. And finally, as illustrated in phantom within FIG. 2, the optional second encapsulant material sub-layer 12b that may serve as a corrosion barrier is otherwise unchanged in shape or location, but as is illustrated in FIG. 2 is optional as illustrated by the phantom representation.

For proper and optimal operation of the luminescent solar concentrator apparatus whose schematic cross-sectional diagram is illustrated in FIG. 1A, whose schematic plan-view diagram is illustrated in FIG. 1B or whose schematic cross-sectional diagram is illustrated in FIG. 2, the width W (i.e., in a horizontal plane as illustrated in FIG. 1A) of the photovoltaic material layer 14 is from about 2 times to about 10 times the thickness T, and more preferably from about 2 times to about 4 times the thickness T (i.e., see also FIG. 1A) of totally internally reflective material located above a photovoltaic material layer 14, as illustrated in FIG. 1A. Generally, such a width W may be readily calculated from the thicknesses disclosed above or measured for the transparent substrate 10 and, as needed, the encapsulant material layer 12 or related encapsulant material sub-layers 12a and 12b, as appropriate.

In addition, a luminescent solar concentrator apparatus in accordance with the embodiments typically has photovoltaic material layer 14 area coverage from about 2 to about 50 percent by area of the transparent substrate 10.

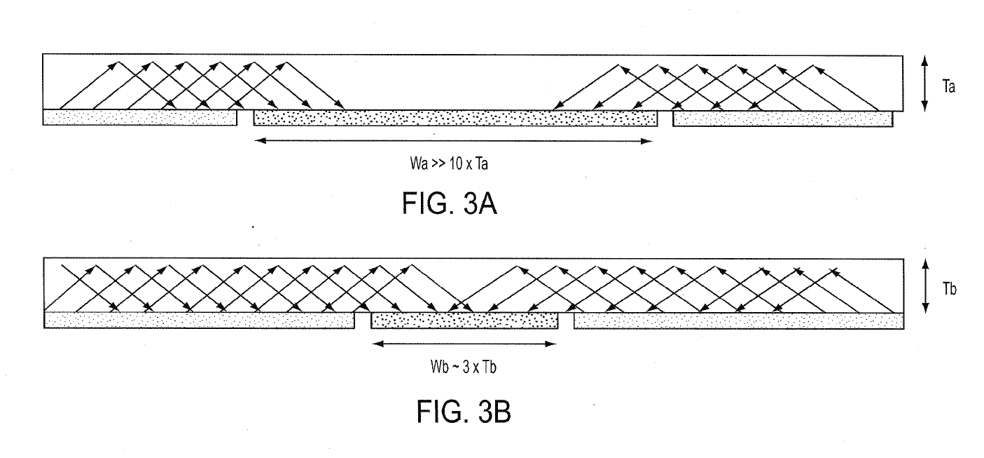

FIG. 3A and FIG. 3B show a plurality of luminescent solar concentrator apparatus constructions illustrating rational for selection of the foregoing photovoltaic material layer 14 width W with respect to thickness T of totally internally reflective material above the photovoltaic material layer 14. As is illustrated in FIG. 3A, a width Wa of a photovoltaic material layer to a thickness Ta of a totally internally reflective material is much greater than about 10 and at that ratio totally internally reflected radiation does not reach a center portion of the photovoltaic material layer. In contrast, and as illustrated within the schematic cross-sectional diagram of FIG. 3B, when a width Wb of a photovoltaic material layer is about 3 times a thickness Tb of a totally internally reflective material located over a photovoltaic material layer, the totally internally reflected radiation is space efficiently and evenly captured by the photovoltaic material layer.

Beyond the above, there are several additional considerations that may merit attention within the context of the luminescent solar concentrator apparatuses in accordance with the embodiments. First, it is desirable that at least the materials from which are comprised the transparent substrate 10 and the encapsulant material layer 12 have a matched index of refraction, that will generally be in a range from about 1.4 to about 1.7. Next, as noted above, the set of luminescent materials that may be included within the luminescent material layer 16 or the luminescent material layers 16′ may be selected to provide particular optical and aesthetic characteristics with respect to the certain particular applications, in addition to luminescent characteristics for solar radiation collection. For example, and without limitation, the luminescent material layers 16 and the luminescent material layers 16′ may be tuned to provide optical and aesthetic characteristics appropriate for energy conservation considerations for new, replacement, retrofit or augmented windows in advanced commercial or residential building construction. In addition, and within the context of the second embodiment, a color of the second encapsulant material sub-layer 12b might be selected to change an apparent color of the complete stack including the luminescent material layers 16′. As well, in certain applications where luminescent solar concentrator apparatuses in accordance with the embodiments are contemplated within the context of solar roofing applications, suitable color tints and hues may be specifically engineered to provide desirable aesthetic results (i.e., terra cotta hues to resemble terra cotta tiles for arid climates, such as but not limited to those within southwestern U.S. residential and commercial applications, as well as earth tone hues to represent wood like tiles or shingles for less arid climates that may include, but are not limited to northeastern U.S. residential and commercial applications). Similar considerations may also be employed within the context of colors, tints and hues for use in window blind constructions that may comprise luminescent solar concentrator apparatus constructions in accordance with the embodiments. In addition, luminescent solar concentrator apparatuses in accordance with the embodiments may also include edge reflector structures so that incident or totally internally reflected radiation is not lost from sidewall edges of the luminescent solar concentrator apparatuses (see, e.g., FIG. 2 for edge reflector 18).

All references, including publications, patent applications and patents cited herein are hereby incorporated by reference in their entireties to the extent allowed, as if each reference was individually and specifically indicated to be incorporated by reference and was set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including” and “containing” are to be construed as open-ended terms (i.e., meaning “including, but not limited to”) unless otherwise noted. The term “connected” is to be construed as partly or wholly contained within, attached to, or joined together, even if there is something intervening.

The recitation of ranges of values herein is merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context.

The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

Thus, the embodiments are illustrative of the invention rather than limiting of the invention. Revisions and modification may be made to methods, materials structures and dimensions of a luminescent solar concentrator apparatus and a related method for fabricating the luminescent solar concentrator apparatus in accordance with the embodiments while still providing a luminescent solar concentrator apparatus an related method for fabricating the luminescent solar concentrator apparatus in accordance with the invention, further in accordance with the accompanying claims.

What is claimed is:

1. A luminescent solar concentrator apparatus comprising:
an optically transparent substrate;
a photovoltaic material layer located over the optically transparent substrate; and
a luminescent material layer also located over the transparent substrate, where the luminescent material layer is not within an incoming optical pathway through at least the optically transparent substrate to the photovoltaic material layer.

2. A luminescent solar concentrator apparatus comprising:
an optically transparent substrate;
a photovoltaic material layer at least partially encapsulated within an optically transparent encapsulant material layer located over the optically transparent substrate; and
a luminescent material layer located contacting the optically transparent encapsulant material layer and not within an incoming optical pathway through at least the optically transparent substrate to the photovoltaic material layer.

3. The luminescent solar concentrator apparatus of claim 2 wherein the optically transparent substrate comprises an optically transparent glass substrate.

4. The luminescent solar concentrator apparatus of claim 2 wherein the optically transparent substrate comprises an optically transparent organic polymer substrate.

5. The luminescent solar concentrator apparatus of claim 2 wherein the optically transparent encapsulant material layer comprises an optically transparent organic polymer encapsulant material.

6. The luminescent solar concentrator apparatus of claim 2 wherein the luminescent material layer comprises a luminescent material selected from the group consisting of organic luminescent dyes and semiconducting polymers.

7. The luminescent solar concentrator apparatus of claim 2 wherein a horizontal width of the photovoltaic material layer is from about 2 to about 10 times a thickness of a totally internally reflective material located over the photovoltaic material layer.

8. The luminescent solar concentrator apparatus of claim 2 wherein a horizontal width of the photovoltaic material layer is from about 2 to about 4 times a thickness of a totally internally reflective material located over the photovoltaic material layer.

9. The luminescent solar concentrator apparatus of claim 2 wherein:
the transparent substrate has thickness from about 1 to about 25 millimeters;
the encapsulant material layer has a thickness from about 0.1 to about 5 millimeters;
the photovoltaic material layer has a thickness from about 0.02 to about 5 millimeters; and
the luminescent material layer has a thickness from about 10 microns to about 3 millimeters.

10. The luminescent solar concentrator apparatus of claim 9 wherein the encapsulant material layer comprises a minimum of two encapsulant material sub-layers, each having a thickness from about 0.1 to about 5 millimeters.

11. The luminescent solar concentrator apparatus of claim 2 wherein the luminescent solar concentrator apparatus has windowpane geometric arrangement.

12. The luminescent solar concentrator apparatus of claim 2 wherein:
the luminescent material layer has a fluorescence quantum yield of at least about 50 percent;
the luminescent material layer has no appreciable overlap of absorption spectrum and fluorescence spectrum; and
the photovoltaic material layer is matched to a fluorescence wavelength range of the luminescent material layer.

13. The luminescent solar concentrator apparatus of claim 2 further comprising a color modifying component that modifies a visual appearance of the luminescent solar concentrator apparatus.

14. The luminescent solar concentrator apparatus of claim 13 wherein the color modifying component is selected from the group consisting of a color filter assembled to the luminescent solar concentrator apparatus, a non-luminescent dye included within the luminescent material layer and a non-luminescent dye included within other than the luminescent material layer.

15. The luminescent solar concentrator apparatus of claim 2 further comprising a barrier layer located upon an outer side of the luminescent solar concentrator apparatus opposite the transparent substrate.

16. A luminescent solar concentrator apparatus comprising:
an optically transparent substrate;
a photovoltaic material layer encapsulated within an optically transparent encapsulant material layer located over one side of the optically transparent substrate; and
a luminescent material layer located over a side of the optically transparent encapsulant material layer opposite the optically transparent substrate.

17. The luminescent solar concentrator apparatus of claim 16 wherein:
the optically transparent substrate comprises a glass material;
the photovoltaic material layer comprises a silicon photovoltaic material;
the optically transparent encapsulant material layer comprises an ethylenevinylacetate polymer material; and
the luminescent material layer comprises a polymethylmethacrylate polymer material.

18. The luminescent solar concentrator apparatus of claim 17 wherein the luminescent material layer also comprises luminescent material selected from the group consisting of luminescent organic dyes and semiconducting polymers.

19. The luminescent solar concentrator apparatus of claim 16 wherein the photovoltaic material layer has a width from about 2 to about 10 times a thickness of the optically transparent substrate and the optically transparent encapsulant material layer over the photovoltaic material layer.

20. The luminescent solar concentrator apparatus of claim 16 wherein the photovoltaic material layer has a width from about 2 to about 4 times a thickness of the optically transparent substrate and the optically transparent encapsulant material layer over the photovoltaic material layer.

21. A luminescent solar concentrator apparatus comprising:
an optically transparent substrate;
a photovoltaic material layer located at least partially encapsulated within an optically transparent encapsulant material layer located over one side of the optically transparent substrate; and
a luminescent material layer located interposed between the optically transparent substrate and the optically transparent encapsulant material layer and not within an incoming optical pathway through at least the optically transparent substrate to the photovoltaic material layer.

22. The luminescent solar concentrator apparatus of claim 21 wherein:
the optically transparent substrate comprises a glass material;
the photovoltaic material layer comprises a silicon photovoltaic material;
the optically transparent encapsulant material layer comprises an ethylenevinylacetate polymer material; and
the luminescent material layer comprises a polymethylmethacrylate polymer material.

23. The luminescent solar concentrator apparatus of claim 22 wherein the luminescent material layer also comprises luminescent material selected from the group consisting of luminescent dyes and semiconducting polymers.

24. The luminescent solar concentrator apparatus of claim 21 wherein the photovoltaic material layer has a width from about 2 to about 10 times a thickness of the optically transparent substrate and the optically transparent encapsulant material layer over the photovoltaic material layer.

25. The luminescent solar concentrator apparatus of claim 21 wherein the photovoltaic material layer has a width from about 2 to about 4 times a thickness of the optically transparent substrate and the optically transparent encapsulant material layer over the photovoltaic material layer.

26. A method for fabricating a luminescent solar concentrator apparatus comprising:
forming over an optically transparent substrate an optically transparent encapsulant material layer including a photovoltaic material layer at least partially encapsulated within the optically transparent encapsulant material layer; and
forming over the optically transparent substrate a luminescent material layer that is not formed interposed between at least the optically transparent substrate and the photovoltaic material layer.

27. The method of claim 26 wherein:
the luminescent material layer is a blanket luminescent material layer; and
the optically transparent encapsulant material layer and the photovoltaic material layer are formed interposed between the optically transparent substrate and the luminescent material layer.

28. The method of claim 26 wherein:
the luminescent material layer is a patterned luminescent material layer; and
the luminescent material layer is formed interposed between the optically transparent substrate and the optically transparent encapsulant material layer.
